(19) United States
(12) Patent Application Publication
(10) Pub. No.: US 2008/0014691 A1
(43) Pub. Date: Jan. 17, 2008

(54) MASK ROM CELL, NOR-TYPE MASK ROM DEVICE, AND RELATED METHODS OF FABRICATION

(75) Inventors: Hee-Seog JEON, Gyeonggi-do (KR); Jeong-Uk HAN, Gyeonggi-do (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Gyeonggi-do (KR)

(21) Appl. No.: 11/774,724

(22) Filed: Jul. 9, 2007

(30) Foreign Application Priority Data
Jul. 10, 2006 (KR) 10-2006-0064577

(51) Int. Cl. H01L 21/8234

(52) U.S. Cl. 438/197

(57) ABSTRACT

A mask read-only memory (ROM) cell, a method for fabricating the mask ROM cell, a NOR-type mask ROM device, and a method for fabricating the NOR-type mask ROM device are disclosed. A mask ROM cell includes a substrate including an ON cell region and an OFF cell region, a first gate electrode disposed in the ON cell region, and a second gate electrode disposed in the OFF cell region. The mask ROM cell also includes a first impurity region disposed in the substrate proximate a sidewall of the first gate electrode, wherein a portion of the first impurity region is disposed under the first gate electrode; and a second impurity region disposed the substrate proximate a sidewall of the second gate electrode, wherein no portion of the second impurity region is disposed under the second gate electrode.

### CROSS-REFERENCE TO RELATED APPLICATION

This application claims priority to Korean Patent Application No. 2006-0064577, filed on Jul. 10, 2006, the subject matter of which is hereby incorporated by reference in its entirety.

### BACKGROUND OF THE INVENTION

1. Field of the Invention

Embodiments of the invention relate to a read-only memory (ROM) cell, a method for fabricating the ROM cell, a ROM device, and a method for fabricating the ROM device. In particular, embodiments of the invention relate to a mask ROM cell and a method for fabricating the mask ROM cell, and a NOR-type mask ROM device and a method for fabricating the NOR-type mask ROM device.

2. Description of the Related Art

A read only memory (ROM) device is a non-volatile memory device capable of storing data even when power is not being supplied to the device (i.e., power is OFF). ROM devices may be generally classified into mask ROM devices, programmable ROM (PROM) devices, electrically programmable ROM (EPROM) devices, erasable and electrically programmable ROM (EEPROM) devices, etc., in accordance with the method used by the device to store data.

A mask ROM device stores data by coding data using a mask when the mask ROM is fabricated. After data is stored in the mask ROM device, the data may be read, but it is not possible to erase or rewrite the data stored in the mask ROM device.

When a mask ROM device is fabricated, a coding process is performed to input data into each cell of the mask ROM device. According to the conventional process for coding data in a mask ROM device, after each cell of the mask ROM device is formed to have a metal-oxide-semiconductor (MOS) transistor, impurities are implanted into some MOS transistors, which then store a data value of “0.”

Particularly, after a plurality of MOS transistors is formed on a substrate, a photoresist pattern is formed on the substrate such that the photoresist pattern exposes a first group of the MOS transistors and covers a second group of MOS transistors. A data value of “0” will be stored in each MOS transistor of the first group, and a data value of “1” will be stored in each MOS transistor of the second group. After the photoresist pattern is formed, impurities having a dopant type different from that of a source/drain region formed at an upper portion of the substrate are implanted into channel regions of the exposed MOS transistors of the first group.

The MOS transistors of the first group, which have channel regions doped with the impurities, each have a higher threshold voltage than the MOS transistors of the second group, which have channel regions that are not doped with the impurities. In accordance with the threshold voltage difference, a MOS transistor may be ON or OFF at a specific gate voltage (i.e., at a specific gate voltage, ON/OFF characteristics of each of the MOS transistors may vary), so the data value stored in each cell may be identified. That is, a transistor having a channel region that is doped with the impurities becomes an OFF transistor that always outputs a data value of “0”, at a specific gate voltage, and a transistor having a channel region that is not doped with the impurities becomes an ON transistor that always outputs a data value of “1” at the specific gate voltage.

A method for fabricating a mask ROM using the above-mentioned coding process is disclosed in Japanese Patent Laid-Open Publication No. 2001-351992.

However, some problems may occur when coding data in a mask ROM using the method described above.

First, an OFF transistor may have a sufficiently high threshold voltage only when the channel region of the OFF transistor is heavily doped with impurities. However, when an ion implantation process for doping the channel region with impurities is performed, in addition to the channel region, a source/drain region may also be heavily doped with the impurities that have a different dopant type from that of the source/drain region. As a result, a junction breakdown voltage between the drain region and the substrate may be decreased.

In addition, when implanting impurities into the channel region under a gate electrode of the OFF transistor with a relatively high concentration, an ion implantation process using relatively high energy needs to be performed. However, in order to prevent the ion implantation process from implanting impurities into a region in which an ON transistor is formed, a mask layer having a relatively large thickness is formed. Generally, a photoresist film is used as the mask layer. Accordingly, forming a relatively fine pattern becomes increasingly difficult as a thickness of the photoresist film increases. Thus, a mask ROM device may not have a relatively high degree of integration when the method described above is used.

Furthermore, an apparatus for performing an ion implantation process uses relatively high energy, so the cost of fabricating a mask ROM device may be relatively high.

### SUMMARY OF THE INVENTION

Embodiments of the invention provide a mask ROM cell having a relatively high junction breakdown voltage, a method for fabricating the mask ROM cell, a NOR-type mask ROM device having a relatively high junction breakdown voltage and a relatively high degree of integration, and a method for fabricating the NOR-type mask ROM device.

In one embodiment, the invention provides a mask read-only memory (ROM) cell comprising a substrate comprising an ON cell region and an OFF cell region, a gate insulation layer disposed on the substrate, a first gate electrode disposed in the ON cell region and on the gate insulation layer, and a second gate electrode disposed in the OFF cell region and on the gate insulation layer. The mask ROM cell further comprises a first impurity region doped with impurities and disposed in a first upper portion of the substrate proximate a sidewall of the first gate electrode, wherein a portion of the first impurity region is disposed under the sidewall of the first gate electrode; and a second impurity region doped with impurities and disposed in a second upper portion of the substrate proximate a sidewall of the second gate electrode, wherein no portion of the second impurity region is disposed under the sidewall of the second gate electrode.

In another embodiment, the invention provides a method for fabricating a mask read-only memory (ROM) cell comprising forming a gate insulation layer on a substrate comprising an ON cell region and an OFF cell region, and forming first and second gate electrodes on the gate insulation layer, wherein the first gate electrode is formed in the ON cell region and the second gate electrode is formed in the OFF cell region. The method further comprises forming a preliminary first impurity region in the ON cell region by implanting first impurities into a first upper portion of the ON cell region proximate the first gate electrode, and implanting second impurities into a portion of the substrate proximate a sidewall of the first gate electrode to form a first impurity region and into a portion of the substrate proximate a sidewall of the second gate electrode to form a second impurity region. In addition, in the method, the first impurity region is disposed in a second upper portion of the ON cell region of the substrate, the first impurity region comprises the first upper portion of the ON cell region, the second impurity region is disposed in an upper portion of the OFF cell region of the substrate, and no portion of the second impurity region is disposed under the sidewall of the second gate electrode.

In yet another embodiment, the invention provides a NOR-type mask read-only memory (ROM) device comprising a substrate comprising an ON cell region, an OFF cell region, and a logic circuit region; a gate insulation layer disposed on the substrate; a first gate electrode disposed on the gate insulation layer and disposed in the ON cell region; and a second gate electrode disposed on the gate insulation layer and disposed in the OFF cell region. The NOR-type mask ROM device further comprises third and fourth gate electrodes disposed on the gate insulation layer and disposed in the logic circuit region; a first impurity region having a first conductivity type disposed in a first upper portion of the ON cell region of the substrate proximate a sidewall of the first gate electrode, wherein a portion of the first impurity region is disposed under the sidewall of the first gate electrode; and a first spacer disposed on the sidewall of the first gate electrode. The NOR-type mask ROM device still further comprises a second impurity region having the first conductivity type disposed in a first upper portion of the OFF cell region of the substrate proximate a sidewall of the second gate electrode, wherein a portion of the second impurity region is disposed under a second spacer disposed on the sidewall of the second gate electrode; a third impurity region having the first conductivity type disposed in a first upper portion of the logic circuit region of the substrate proximate a sidewall of the third impurity region; a third spacer disposed on the sidewall of the third impurity region; a fourth impurity region having a second conductivity type disposed in a second upper portion of the logic circuit region of the substrate proximate a sidewall of the fourth gate electrode; and a fourth spacer disposed on the sidewall of the fourth impurity region.

In still another embodiment, the invention provides a method for fabricating a NOR-type mask read-only memory (ROM) device, the method comprising forming a gate insulation layer on a substrate comprising an ON cell region, an OFF cell region, and a logic circuit region; forming first through fourth gate electrodes on the gate insulation layer, wherein the first gate electrode is formed in the ON cell region, the second gate electrode is formed in the OFF cell region, and the third and fourth gate electrodes are formed in the logic circuit region; and implanting first impurities having a first conductivity type into a first upper portion of the ON cell region of the substrate proximate the first gate electrode to form a preliminary first impurity region and into a first upper portion of the logic circuit region of the substrate proximate the third gate electrode to form a preliminary third impurity region. The method further comprises forming a first spacer on a sidewall of the first gate electrode, a second spacer on a sidewall of the second gate electrode, a third spacer on a sidewall of the third gate electrode, and a fourth spacer on a sidewall of the fourth gate electrode; implanting second impurities having the first conductivity type into a second upper portion of the ON cell region of the substrate proximate the first gate electrode to form a first impurity region, into an upper portion of the OFF cell region of the substrate proximate the second gate electrode to form a second impurity region, and into a second upper portion of the logic circuit region of the substrate proximate the third gate electrode to form a third impurity region; and implanting fourth impurities having a second conductivity type into a first upper portion of the substrate proximate the fourth spacer to form a fourth impurity region. Also, in the method, a portion of the first impurity region is disposed under the sidewall of the first gate electrode and a portion of the second impurity region is disposed under the second spacer.

### BRIEF DESCRIPTION OF THE DRAWINGS

Embodiments of the invention will be described herein with reference to the accompanying drawings, in which:

FIG. 1 is a cross-sectional view illustrating cells of a mask read-only memory (ROM) device in accordance with an embodiment of the invention;

FIGS. 2 to 4 are cross-sectional views illustrating a method for fabricating the cells of the mask ROM device shown in FIG. 1 in accordance with an embodiment of the invention;

FIG. 5 is a cross-sectional view illustrating a mask ROM device in accordance with an embodiment of the invention;

FIG. 6 is a top view illustrating a cell region of the mask ROM device of FIG. 5 in accordance with an embodiment of the invention; and,

FIGS. 7 to 13 are cross-sectional views illustrating a method for fabricating the mask ROM device of FIGS. 5 and 6 in accordance with an embodiment of the invention.

### DESCRIPTION OF EMBODIMENTS

In the drawings, the sizes and relative sizes of layers and regions may not be drawn to scale. In addition, when a first element or layer is referred to as being “on” or “connected with” a second element or layer, the first element or layer may be directly on or connected with the second element or layer, or intervening elements or layers may be present. In contrast, when a first element is referred to as being “directly on” or “directly connected with” a second element or layer, there are no intervening elements or layers present. In the drawings, like reference symbols indicate like or similar elements throughout. As used herein, the term “and/or” comprises any and all combinations of one or more of the listed items.

It will be understood that, although the terms “first”, “second”, “third”, etc., may be used herein to describe various elements, components, regions, layers, and/or sections, these elements, components, regions, layers, and/or sections should not be limited by these terms. These terms are only used to distinguish one element, component, region, layer, or section from another element, component region, layer, or section. Thus, a first element, component, region, layer, or section discussed below could be referred to as a second element, component, region, layer, or section without departing from the scope of the invention as defined by the accompanying claims.

In addition, spatially relative terms, such as “below,” “above,” “under,”1 “upper”, and the like, may be used herein for ease of description to describe one element or feature's relationship to another element(s) or feature(s) as illustrated in the drawings. However, the spatially relative terms are intended to encompass different orientations of the device in use or operation in addition to the orientation depicted in the drawings. For example, if a device in the drawings is turned over, elements described as “below” other elements or features would then be oriented “above” the other elements or features. Thus, the term “below” can encompass both an orientation of above and below. The device may be otherwise oriented (e.g., rotated 90 degrees) and the spatially relative descriptors used herein should be interpreted accordingly.

Embodiments of the invention are described herein with reference to cross-sectional illustrations that are schematic illustrations of idealized embodiments (and intermediate structures) of embodiments of the invention. As such, variations from the shapes of the illustrations as a result of, for example, manufacturing techniques and/or tolerances, are to be expected. Thus, embodiments of the invention should not be construed as limited to the particular shapes of regions illustrated herein but are to include deviations in shapes that result, for example, when a device is manufactured. For example, an ion-injected region illustrated as a rectangle will, typically, have rounded or curved features and/or a gradient of injected ion concentration at its edges rather than a binary change from injected to non-implanted region. Likewise, a buried region formed by ion implantation may result in some implantation in the region between the buried region and the surface through which the ion implantation takes place. Thus, the regions illustrated in the figures are schematic in nature and their shapes are not intended to illustrate the actual shape of a region of a device and are not intended to limit the scope of the present invention.

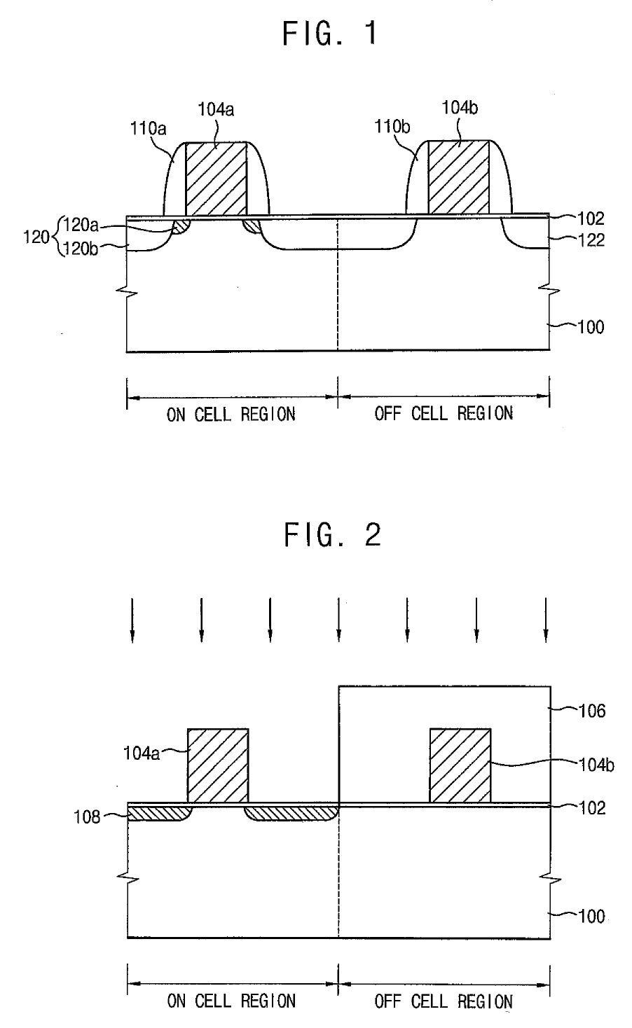

FIG. 1 is a cross-sectional view illustrating cells of a mask read-only memory (ROM) device in accordance with an embodiment of the invention. Referring to FIG. 1, a substrate 100 comprises an ON cell region and an OFF cell region. In accordance with an embodiment of the invention, the substrate 100 may comprise single-crystalline silicon lightly doped with P-type impurities.

The cells of the mask ROM device comprise an ON cell transistor and an OFF cell transistor. The ON cell transistor maintains an ON state during a read operation, whereas the OFF cell transistor maintains an OFF state during a read operation. The ON cell transistor is formed in the ON cell region of the substrate 100, and the OFF cell transistor is formed in the OFF cell region of the substrate 100. Each of the ON cell transistor and the OFF cell transistor may be an N-channel MOS (NMOS) transistor or a P-channel MOS (PMOS) transistor. In the embodiment illustrated in FIG. 1, the ON cell transistor and the OFF cell transistor are NMOS transistors.

The ON cell transistor disposed in the ON cell region will now be described. A gate insulation layer 102 is disposed on the substrate 100. The gate insulation layer 102 may comprise silicon oxide. The silicon oxide may be formed by performing a heat treatment on the substrate 100.

A first gate electrode 104a is disposed on the gate insulation layer 102 and in ON cell region. The first gate electrode 104a may comprise a conductive material. In particular, the first gate electrode 104a may comprise metal, a semiconductor material such as doped poly-crystalline silicon, etc.

A first spacer 11a comprising an insulating material is disposed on a sidewall of the first gate electrode 104a. In an embodiment of the invention, the first spacer 110a comprises silicon nitride. Throughout the application, though a plurality of a component may be shown in the drawings, description may be limited, in whole or in part, to one of the plurality for convenience of description.

A first impurity region 120 doped with N-type impurities is disposed in an upper portion of the substrate 100 proximate the sidewall of the first gate electrode 104a. In particular, a portion of the first impurity region 120 of the substrate 100 is disposed under the sidewall of the first gate electrode 104a.

The first impurity region 120 comprises a first doping region 120a and a second doping region 120b. The first and second doping regions 120a and 120b having first and second impurity concentrations, respectively, are disposed in the upper portion of the substrate 100 proximate the sidewall of the first gate electrode 104a. Particularly, a portion of the first doping region 120a is disposed under the sidewall of the first gate electrode 104a. In addition, a portion of the second doping region 120b is disposed under the first spacer 110a and no portion of the second doping region 120b is disposed under the sidewall of the first gate electrode 104a. Also, the second doping region 120b makes contact with the first doping region 120a. The second impurity concentration may be higher than the first impurity concentration. In addition, the second doping region 120b may have a greater depth than the first doping region 120a.

When a voltage greater than a threshold voltage is applied to the first gate electrode 104a of the ON cell transistor, a channel electrically connected to the first impurity region 120 is formed at an upper portion of the substrate 100 under the first gate electrode 104a, and the ON cell transistor maintains an ON state.

The OFF cell transistor formed in the OFF cell region will now be described. The gate insulation layer 102 is disposed on the substrate 100. A second gate electrode 104b is formed on the gate insulation layer 102 and in the OFF cell region. The second gate electrode 104b may comprise a material that is substantially the same as a material that the first gate electrode 104a comprises.

A second spacer 110b comprising an insulating material is formed on a sidewall of the second gate electrode 104b. The second spacer 110b may comprise a material that is substantially the same as a material that the first spacer 110a comprises.

A second impurity region 122 doped with N-type impurities is disposed in an upper portion of the substrate 100 proximate the sidewall of the second gate electrode 104b. A portion of the second impurity region 122 is disposed under the second spacer 110b, and no portion of the second impurity region 122 is disposed under the second gate electrode 104b. The second impurity region 122 may have an impurity concentration that is substantially the same as that of the second doping region 120b.

When a voltage is applied to the second gate electrode 104b of the OFF cell transistor, a channel electrically connected to the second impurity region 122 is not formed in an upper portion of the substrate 100 under the second gate electrode 104b. Therefore, the OFF cell transistor maintains an OFF state regardless of a gate voltage applied to the second gate electrode 104b.

The ON cell region and the OFF cell region may be disposed adjacent to one another as illustrated in FIG. 1. In addition, a portion (e.g., an edge portion) of the first impurity region 120 may be connected to a portion (e.g., an edge portion) of the second impurity region 122.

FIGS. 2 through 4 are cross-sectional views illustrating a method for fabricating the cells of the mask ROM device shown in FIG. 1 in accordance with an embodiment of the invention.

Referring to FIG. 2, a gate insulation layer 102 is formed on a substrate 100 comprising an ON cell region and an OFF cell region. The substrate 100 may comprise single-crystalline silicon lightly doped with P-type impurities. The gate insulation layer 102 may be formed by thermally oxidizing the substrate 100.

In addition, a conductive layer is formed on the gate insulation layer 102. The conductive layer may be formed from polysilicon, a metal, etc. In accordance with an embodiment of the invention, the conductive layer is formed from polysilicon that may be easily removed through a dry etching process.

The conductive layer may be patterned through a photolithography process to form a first gate electrode 104a on the ON cell region and a second gate electrode 104b on the OFF cell region.

A mask pattern 106 is formed on the OFF cell region to cover the second gate electrode 104b. A photoresist pattern formed through a photolithography process may serve as the mask pattern 106. A preliminary impurity region 108 having a first impurity concentration is formed in an upper potion of the substrate 100 by implanting N-type impurities into a portion of the ON cell region of the substrate 100 that is exposed by the mask pattern 106. A portion of preliminary impurity region 108 may be disposed under the sidewall of the first gate electrode 104a.

After implanting the N-type impurities into the ON cell region, the mask pattern 106 may be removed. When the photoresist pattern is used as the mask pattern 106, the mask pattern 106 may be removed through an ashing process and/or a stripping process.

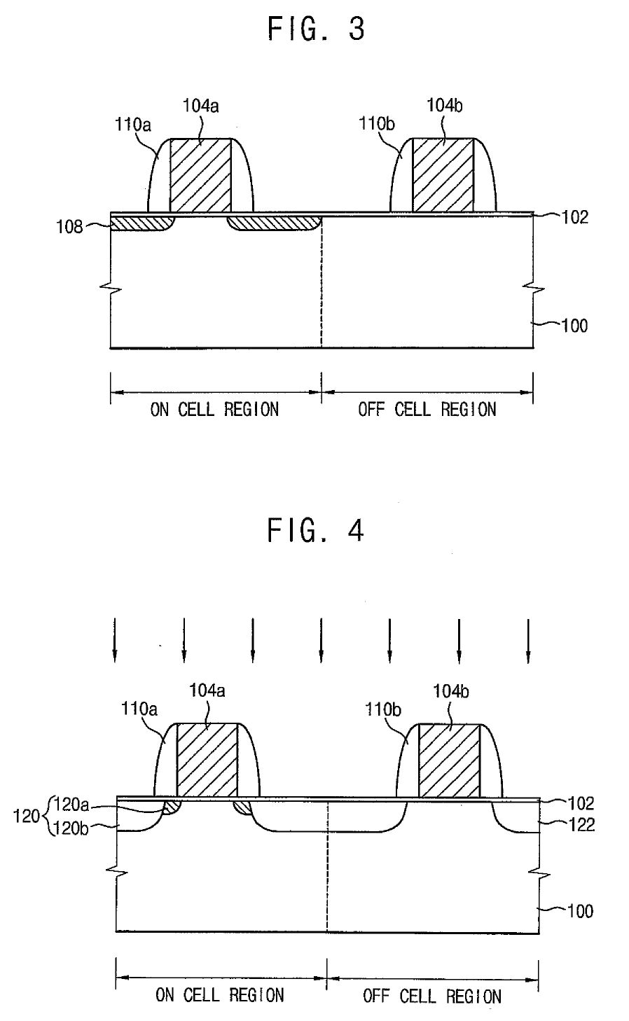

Referring to FIG. 3, an insulation layer is formed on the gate insulation layer 102 to cover the first and second gate electrodes 104a and 104b. The insulation layer may be formed by depositing silicon nitride on the gate insulation layer 102 through a low pressure chemical vapor deposition (LPCVD) process. The insulation layer may be partially removed through an anisotropic etching process to form a first spacer 110a on a sidewall of the first gate electrode 104a and a second spacer 110b on a sidewall of the second gate electrode 104b.

The first and second spacers 110a and 110b may each be formed to have a relatively large thickness to substantially prevent impurities doped into the substrate 100 during a subsequent implantation process from diffusing to a portion of the substrate 100 under either of the first and second gate electrodes 104a and 104b.

Referring to FIG. 4, a first impurity region 120 is formed in the ON cell region and a second impurity region 122 is formed in the OFF cell region by implanting N-type impurities into portions of the substrate 100 that are not covered by the gate electrodes 104a and 104b and the spacers 110a and 110b.

The second impurity region 122 may have an impurity concentration higher than that of the preliminary first impurity region 108. In addition, the second impurity region 122 may have a greater depth than that of the preliminary first impurity region 108.

The first impurity region 120 comprises the preliminary first impurity region 108, so a portion of the first impurity region 120 is disposed under the sidewall of the first gate electrode 104a.

The first impurity region 120 has a lightly doped drain (LDD) structure comprising a first doping region 120a and a second doping region 120b. The first and second doping regions 120a and 120b having first and second impurity concentrations, respectively, are formed in an upper portion of the substrate 100 proximate the sidewall of the first gate electrode 104a. Particularly, a portion of the first doping region 120a is disposed under the sidewall of the first gate electrode 104a. In addition, a portion of the second doping region 120b is disposed under the first spacer 110a, and no portion of the second doping region 120b is disposed under the sidewall of the first gate electrode 104a. Also, the second doping region 120b makes contact with the first doping region 120a. The second doping region 120b may have a greater depth than the first doping region 120a. In addition, the preliminary first impurity region 108 may be described as being formed in a first upper portion of the ON cell region and the first impurity region 120 may be described as being formed in a second upper portion of the ON cell region. Also, the first impurity region 120 comprises the preliminary first impurity region 108, so the first and second upper portions overlap.

In addition, a portion of the second impurity region 122 disposed in the OFF cell region is disposed under the second spacer 110b, but no portion of the second impurity region 122 is disposed under the second gate electrode 104b in part because impurities were not doped into the OFF cell region during the process for forming the preliminary first impurity region 108.

The impurities doped into the substrate 100 when forming the second impurity region 122 may be diffused into other portions of the substrate 100 during subsequent processes performed at relatively high temperatures. Thus, the second spacer 110b is formed to have a relatively large thickness to substantially prevent the impurities doped into the substrate 100 when forming the second impurity region 122 from diffusing (during a subsequent process) to any portion of the substrate 100 disposed under the second gate electrode 104b. The ON and OFF cell transistors may be formed in the ON and OFF cell regions, respectively, through the processes described above.

In accordance with an embodiment of the invention, impurities are not implanted into a channel region of the OFF cell transistor when the OFF cell transistor is formed. In particular, impurities are not implanted into a region of the substrate 100 disposed under the second gate electrode 104b of the OFF cell transistor when the OFF cell transistor is formed. Therefore, a mask ROM device in accordance with an embodiment of the invention may have improved operating performance and improved reliability.

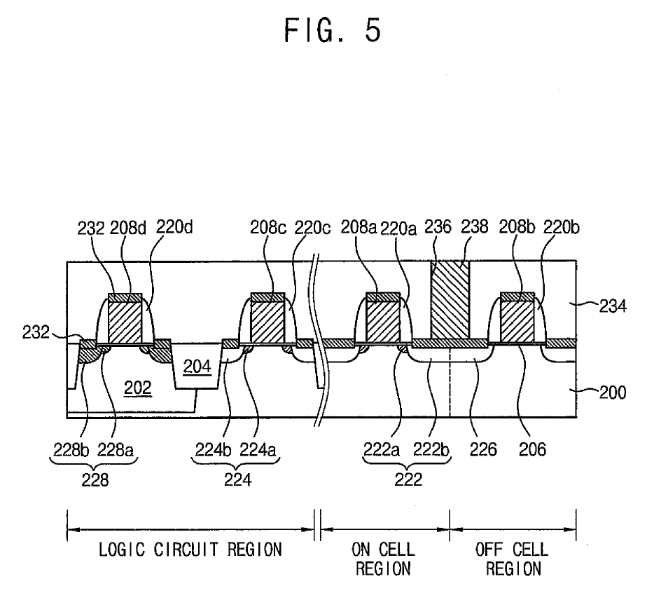

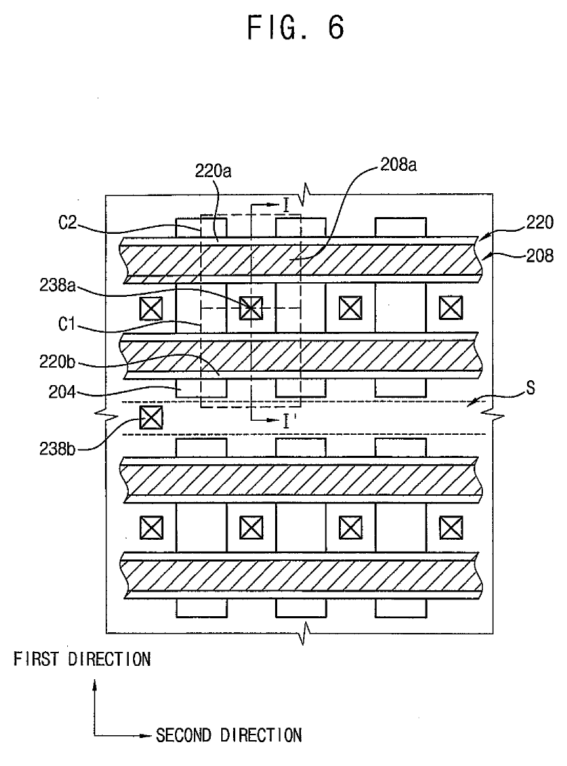

FIG. 5 is a cross-sectional view illustrating a mask ROM device in accordance with an embodiment of the invention, and FIG. 6 is a top view illustrating a cell region of the mask ROM device of FIG. 5 in accordance with an embodiment of the invention.

Referring to FIGS. 5 and 6, a substrate 200 comprises a cell region and a logic circuit region. The cell region comprises an ON cell region and an OFF cell region. In the cell region, an ON cell transistor and an OFF cell transistor are arranged so that the mask ROM device in which they are disposed stores the desired data. For example, in FIG. 6, a first area C1 may be designated as the OFF cell region, and remaining areas, including a second area C2, may be designated as the ON cell region. In the embodiment illustrated in FIGS. 5 and 6, the OFF cell transistor is formed in the first area C1 and the ON cell transistor is formed in second area C2.

Additionally, an NMOS transistor and a PMOS transistor are disposed in the logic circuit region.

Transistors formed in the cell region and the logic circuit region will now be described in more detail.

The substrate 200 may comprise single-crystalline silicon lightly doped with P-type impurities. An N-type impurity well 202 having a predetermined depth is formed in an upper portion of the substrate 200. A PMOS transistor is formed on the N-type impurity well 202 in the logic circuit region.

A plurality of isolation layer patterns 204 defining an active region are formed in an upper portion of the substrate 200. Particularly, in the cell region, the isolation layer patterns 204 each have an island shape and extend along a first direction, and at least one of the isolation patterns 204 is at least partially disposed in an upper portion of the ON cell region and an upper portion of the OFF cell region. In addition, the isolation layer patterns 204 in the cell region that are adjacent to one another along a second direction perpendicular to the first direction are disposed parallel to one another. In the logic circuit region, an isolation layer pattern 204 may separate the NMOS transistor and the PMOS transistor. As used herein, when an element is said to “extend” along, for example, the first direction, it means that the length of the element along the first direction is greater than the length of the element along a direction perpendicular to that direction (which is the second direction in this case), wherein both of the directions are parallel to the working surface of the corresponding substrate.

A gate insulation layer 206 is formed on the substrate 200. The gate insulation layer 206 may comprise silicon oxide formed by thermally treating the substrate 200.

Referring to FIG. 6, a plurality of gate electrode lines 208 is formed on the gate insulation layer 206 (of FIG. 5), wherein at least a portion of one of the gate electrode lines 208 is formed in the ON cell region and at least a portion of one of the gate electrode lines 208 is formed in the OFF cell region. The gate electrode lines 208 each have a linear shape and extend in the second direction. Particularly, the gate electrode lines 208 are arranged to perpendicularly cross the isolation layer patterns 204. In accordance with one embodiment of the invention, as shown in FIG. 6, for each isolation layer pattern 204, two gate electrode lines 208 cross (and are partially disposed on) the isolation layer pattern 204.

A portion of the gate electrode line 208 disposed at least partially in the ON cell region (i.e., the second area C2) may serve as a gate electrode of the ON cell transistor and may be referred to hereafter as a first gate electrode 208a. The gate electrode line 208 disposed at least partially in the ON cell region may be referred to herein as a first gate electrode line 208. In addition, a first portion of the gate electrode line 208 disposed at least partially in the OFF cell region (i.e., the first area C1) may serve as a gate electrode of the OFF cell transistor and may be referred to hereafter as a second gate electrode 208b. In addition, the gate electrode line 208 disposed at least partially in the OFF cell region may be referred to as a second gate electrode line 208. Also, a second portion of second gate electrode line 208 may serve as a gate electrode of another ON cell transistor disposed in the ON cell region.

As illustrated in FIG. 5, third and fourth gate electrodes 208c and 208d are disposed on the gate insulation layer 206 and in the logic circuit region. The first through fourth gate electrodes 208a, 208b, 208c, and 208d may comprise semiconductor materials such as doped polysilicon, a metal, etc. In accordance with an embodiment of the invention, the first through fourth gate electrodes 208a, 208b, 208c, and 208d comprise doped polysilicon.

A plurality of spacers, each comprising at least one insulation material, is formed on sidewalls of the gate electrode lines 208 and the third and fourth gate electrodes 208c and 208d. The spacers may comprise silicon nitride. Hereinafter, spacers formed on the sidewalls of the first through fourth gate electrodes 208a, 208b, 208c, and 208d may be referred to as first through fourth spacers 220a, 220b, 220c, and 220d, respectively.

A first impurity region 222 doped with N-type impurities is disposed in an upper portion the ON cell region of the substrate 200 proximate a sidewall of the first gate electrode 208a. In addition, a portion of the first impurity region 222 is disposed under the sidewall of the first gate electrode 208a.

The first impurity region 222 has an LDD structure and comprises a first doping region 222a and a second doping region 222b. The first and second doping regions 222a and 222b have first and second impurity concentrations, respectively. The first impurity concentration may be lower than the second impurity concentration. A portion of the first doping region 222a is disposed under the sidewall of the first gate electrode 208a. A portion of the second doping region 222b is disposed under the first spacer 220a, and no portion of the second doping region 222b is disposed under the sidewall of the first gate electrode 208a. In addition, the second doping region 222b makes contact with the first doping region 222a. Also, the second doping region 222b may have a greater depth than the first doping region 222a.

When a voltage that is higher than a threshold voltage is applied to the first gate electrode 208a of the ON cell transistor, a channel may be formed at an upper portion of the substrate 200 under the first gate electrode 208a, and the ON cell transistor maintains an ON state.

A second impurity region 226 doped with N-type impurities is disposed in an upper portion of the OFF cell region of the substrate 200 proximate the sidewall of the second gate electrode 208b. A portion of the second impurity region 226 is disposed under the second spacer 220b, but no portion of the second impurity region 226 is disposed under the second gate electrode 208b. The second impurity region 226 may have an impurity concentration that is substantially the same as the second impurity concentration.

When a voltage is applied to the second gate electrode 208b of the OFF cell transistor, a channel electrically connected to the second impurity region 226 is not formed in an upper portion of the substrate 200 under the second gate electrode 208b. Therefore, the OFF cell transistor maintains an OFF state regardless of a gate voltage applied to the second gate electrode 208b.

Referring to FIG. 6, source regions of the ON cell transistors and the OFF cell transistors, each of which is arranged in parallel with one another in the second direction, are connected to one another, thereby forming a common source region S.

Referring again to FIG. 5, a third impurity region 224 doped with N-type impurities is disposed in an upper portion of the logic circuit region of the substrate 200 proximate a sidewall of the third gate electrode 208c. A portion of the third impurity region 224 is disposed under the sidewall of the third gate electrode 208c. The third impurity region 224, like the first impurity region 222, has an LDD structure comprising a third doping region 224a and a fourth doping region 224b. The third and fourth doping regions 224a and 224b, which have third and fourth impurity concentrations, respectively, are formed in an upper portion of the substrate 200 proximate the sidewall of the third gate electrode 208c. In particular, a portion of the third doping region 224a is disposed under the sidewall of the third gate electrode 224a. In addition, a portion of the fourth doping region 224b is disposed under the third spacer 220c, but no portion of the fourth doping region 224b is disposed under the sidewall of the third gate electrode 208c. The third impurity concentration may be lower than the fourth impurity concentration.

A fourth impurity region 228 doped with P-type impurities is formed in an upper portion of the logic circuit region of the substrate 200 proximate a sidewall of the fourth gate electrode 208d. A portion of the fourth impurity region 228 is disposed under the sidewall of the fourth gate electrode 208d. The fourth impurity region 228 may have an LDD structure substantially the same as those of the first and third impurity regions 222 and 224, except that the fourth impurity region 228 may comprise conductive impurities of a different type from those of the first and third impurity regions 222 and 224.

A metal silicide layer pattern 232 is formed on portions of the substrate 200 disposed between the spacers 220a and 220b that are adjacent to one another, between the third spacer 208c and the isolation layer pattern 204, and between the fourth spacer 208d and the isolation layer pattern 204. That is, the metal silicide layer pattern 232 is formed on the first through fourth impurity regions 222, 226, 224, and 228. In other words, the metal silicide layer pattern 232 is disposed on a portion of an upper surface of the substrate 200 proximate the first spacer 220a and is disposed on a portion of an upper surface of the substrate 200 proximate the second spacer 220b.

The metal silicide layer pattern 232 is also formed on the first through fourth gate electrodes 208a, 208b, 208c, and 208d. A structure comprising the gate electrodes 208a, 208b, 208c, and 208d and the metal silicide layer pattern 232 may have a reduced resistance because of the metal silicide layer pattern 232.

The metal silicide layer pattern 232 may comprise at least one of, for example, tungsten silicide, cobalt silicide, titanium silicide, etc. Although the metal silicide layer pattern 232 may comprise one or a combination of those substances, it preferably comprises only one of those substances.

An insulating interlayer 234 is formed on the substrate 200 to cover the first through fourth gate electrodes 208a, 208b, 208c, and 208d. An opening 236 is formed through the insulating interlayer 234 exposing at least one impurity region of the first through fourth impurity regions 222, 226, 224, and 228. A plug is formed in the opening 236 to make contact with the impurity region.

Particularly, in the cell region, a bit line plug 238a (see FIG. 6) is formed to make contact with an impurity region serving as a common drain region for transistors that cross over the isolation layer patterns 204. A common source plug 238b (see FIG. 6) is formed to make contact with an impurity region serving as a common source region for transistors disposed in the cell region. In the cell region, the impurity regions serving as the common source region are connected to one another along the second direction.

A wiring (not shown) may be formed on the bit line plug 238a and the common source plug 238b to connect the bit line plug 238a to the common source plug 238b. The wiring may comprise a bit line, a common source lines etc.

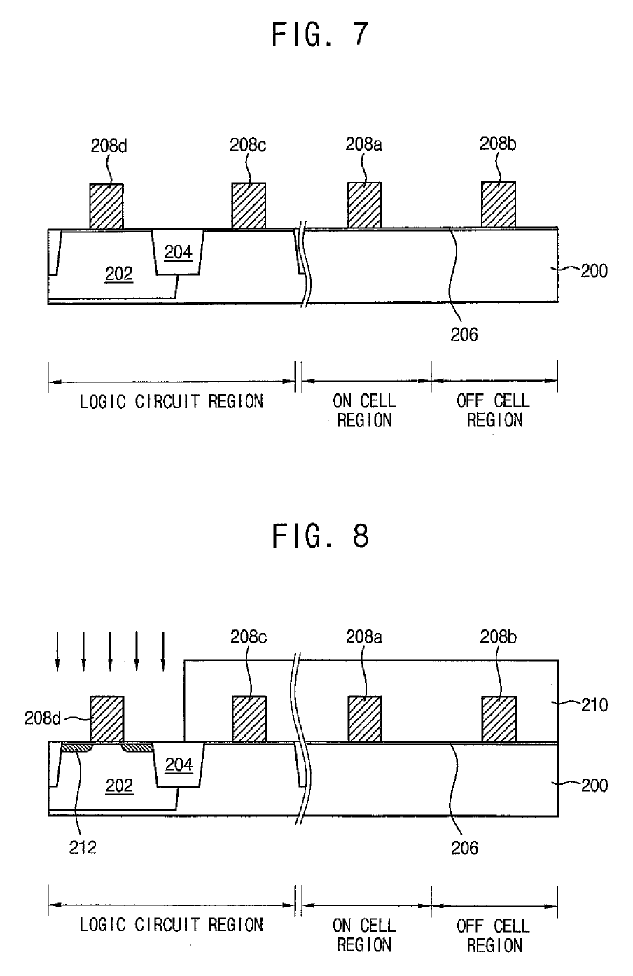

FIGS. 7 through 13 are cross-sectional views illustrating a method for fabricating the mask ROM device of FIGS. 5 and 6 in accordance with an embodiment of the invention.

Referring to FIG. 7, a substrate 200 comprising a cell region and a logic circuit region is prepared. The cell region comprises an ON cell region and an OFF cell region. The substrate 200 comprises single-crystalline silicon lightly doped with P-type impurities.

A first photoresist pattern (not shown) is formed on the substrate 200, wherein the first photoresist pattern exposes an upper portion of the logic circuit region and a PMOS transistor will subsequently be formed on the upper portion of the logic circuit region.

N-type impurities having a low concentration are implanted into the exposed region of the substrate 200 using the first photoresist pattern as an ion implantation mask. Thus, an N-type impurity well 202 that will serve as a channel region of the PMOS transistor may be formed.

In addition, isolation layer patterns 204 are formed in upper portions of the substrate 200 to define active regions.

Particularly, trenches (not shown) are formed in the substrate 200 to define isolation regions by etching the substrate 200. In the cell region, a trench is formed to have an island shape extending in the first direction. In the logic circuit region, a trench is formed in a portion of the logic circuit region disposed between a region of the logic circuit region where an NMOS transistor will be formed and a region of the logic circuit region where the PMOS transistor will be formed, and the trench separates those regions. In addition, the trenches are filled with an insulating material to form the isolation layer patterns 204.

The isolated trenches formed in the cell region may be formed such that trenches in the cell region that are adjacent to one another along the second direction are parallel to one another. Therefore, the isolation layer patterns 204 formed in the cell region that are adjacent to one another along the second direction may be parallel to one another.

Additionally, a gate insulation layer 206 is formed on the active region of the substrate 200. The gate insulation layer 206 may be formed by thermally oxidizing the substrate 200.

A conductive layer (not shown) is formed on the gate insulation layer 206. The conductive layer may be formed from polysilicon, a metal, etc. In accordance with an embodiment of the invention, the conductive layer is formed from polysilicon that is easily removed through a dry etching process.

The conductive layer is patterned through a photolithography process to form gate electrode lines 208 on the cell region (as illustrated in FIG. 6) and gate electrodes 208c and 208d in the logic circuit region, wherein the gate electrodes 208c and 208d each have an island shape.

Referring to FIG. 6, each of the gate electrode lines 208 formed in the cell region has a linear shape extending along a second direction that is perpendicular to the first direction. In accordance with an embodiment of the invention, for each isolation layer pattern 204, portions of two gate electrode lines 208 are formed on the isolation layer pattern 204.

The gate electrode lines 208 comprises a first portion formed in the ON cell region (see C2 of FIG. 6) of the substrate 200. In addition, the first portion of the gate electrode lines 208 may serve as a gate electrode of the ON cell transistor and may be referred to herein as a first gate electrode 208a. Also, the gate electrode lines 208 comprises a second portion formed in the OFF cell region (see C1 of FIG. 6) of the substrate 200. In addition, the second portion of the gate electrode lines 208 may serve as a gate electrode of the OFF cell transistor and may be referred to herein as a second gate electrode 208b.

Additionally, a third gate electrode 208G is a portion of a conductive layer pattern that serves as a gate electrode of an NMOS transistor in the logic circuit region, and a fourth gate electrode 208d is a portion of a conductive layer pattern that serves as a gate electrode of a PMOS transistor in the logic circuit region.

Referring to FIG. 8, a second photoresist pattern 210, which exposes a PMOS region of the logic circuit region, is formed on the substrate 200. The PMOS region of the logic circuit region is a region of the logic circuit region where the PMOS transistor will subsequently be disposed (i.e., where the PMOS transistor is being formed). P-type impurities are implanted into the exposed PMOS region of the logic circuit region of the substrate 200 using the second photoresist pattern 210 and the fourth gate electrode 208d as ion implantation masks. Thus, a preliminary fourth impurity region 212 may be formed. The second photoresist pattern 210 may be removed using an ashing process and/or a stripping process.

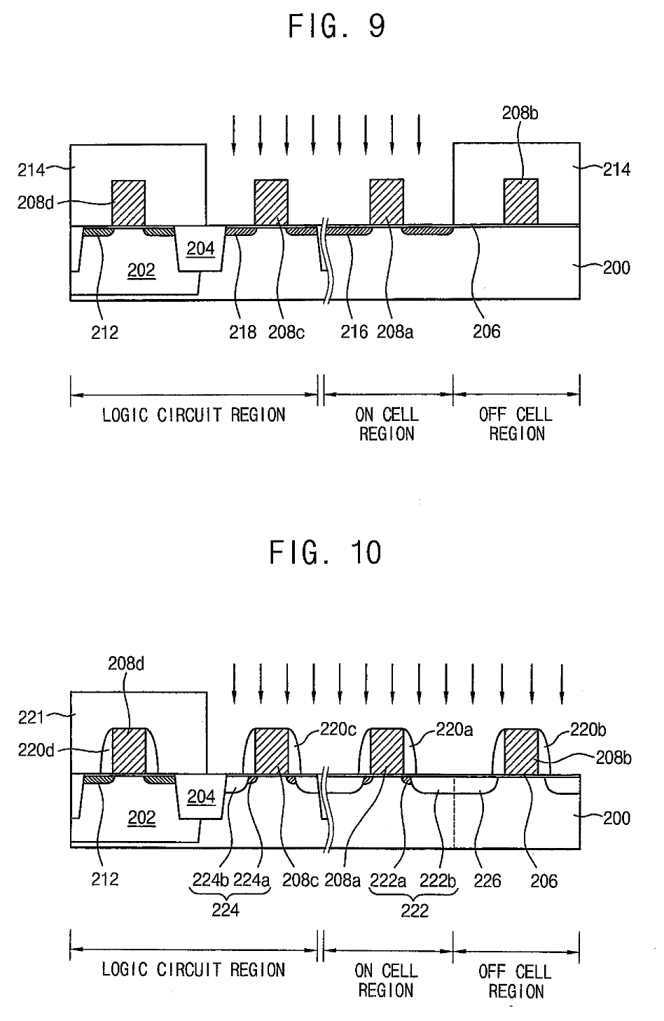

Referring to FIG. 9, a third photoresist pattern 214 is formed on the substrate 200 to cover the second and fourth gate electrodes 208b and 208d. That is, the third photoresist pattern 214 covers the OFF cell region and the PMOS region of the logic circuit region. In addition, the third photoresist pattern 214 exposes the ON cell region and an NMOS region of the logic circuit region. The NMOS region of the logic circuit region is where the NMOS transistor will subsequently be disposed (i.e., where the NMOS transistor is being formed).

N-type impurities are implanted into portions of the ON cell region of the substrate 200 proximate the first gate electrode 208a and portions of the logic circuit region of the substrate 200 proximate the third gate electrode 208c using the third photoresist pattern 214 and the first and third gate electrodes 208a and 208c as ion implantation masks. A preliminary first impurity region 216 having a first impurity concentration is formed in a first upper portion of the ON cell region of the substrate 200 proximate the first gate electrode 208a, and a preliminary third impurity region 218 also having the first impurity concentration is formed in a first upper portion of the logic circuit region of the substrate 200 proximate the third gate electrode 208c. That is, the N-type impurities are implanted into the first upper portion of the ON cell region and into the first upper portion of the logic circuit region.

As illustrated in FIG. 9, the third photoresist pattern 214 is formed to cover both the OFF cell region and the PMOS region of the logic circuit region. Thus, coding predetermined data may be achieved by covering the OFF cell region using a photoresist pattern. Therefore, an additional photolithography process for coding data, an ion implantation process for implanting impurities into a channel region, etc., are not required in a mask ROM device in accordance with an embodiment of the invention.

The third photoresist pattern 214 may be removed using an ashing process and/or a stripping process.

Referring to FIG. 10, an insulation layer (not shown) is formed on the substrate 200 to cover the gate electrode lines 208 and the third and fourth gate electrodes 208c and 208d. The insulation layer may be formed by depositing silicon nitride.

The insulation layer is partially removed through an anisotropic etching process to form spacers on sidewalls of the gate electrode lines 208 and the third and fourth gate electrodes 208 and 208d. Hereinafter, spacers formed on the sidewalls of the first and second gate electrodes 208a and 208b may be referred to as first and second spacers 220a and 220b, respectively. Additionally, spacers formed on the sidewalls of the third and fourth gate electrodes 208c and 208d may be referred to herein as third and fourth spacers 220c and 220d, respectively.

In addition, a fourth photoresist pattern 221 is formed on the substrate 200 to cover the PMOS region disposed in the logic circuit region.

N-type impurities are implanted into the ON cell region, the OFF cell region, and the NMOS region of the logic circuit region with a relatively high concentration to form a first impurity region 222 in the ON cell region, a second impurity region 226 in the OFF cell region, and a third impurity region 224 in the NMOS region of the logic circuit region. In particular, the N-type impurities may be implanted into a second upper portion of the ON cell region of the substrate 200 proximate the first gate electrode 208a to form the first impurity region 222, into an upper portion of the OFF cell region of the substrate 200 proximate the second gate electrode 208b to form the second impurity region 226, and into a second upper portion of the logic circuit region of the substrate 200 proximate the third gate electrode 208c to form the third impurity region 224. In addition, the first and second upper portions of the ON cell region may overlap and the first and second upper portions of the logic circuit region may overlap.

A portion of the first impurity region 222 is disposed under a sidewall of the first gate electrode 208a, which is disposed in the ON cell region. The first impurity region 222 may have an LDD structure comprising a first doping region 222a and a second doping region 222b. In that case, the first doping region 222a having a first impurity concentration is disposed in an upper portion of the substrate 200, wherein a portion of the first doping region 222a is disposed under the sidewall of the first gate electrode 208a, and the second doping region 222b having a second impurity concentration is formed in an upper portion of the substrate 200, wherein a portion of the second doping region 222b is disposed under the first spacer 220a. The second doping region 222b makes contact with the first doping region 222a.

The third impurity region 224 is formed in the NMOS region in the logic circuit region and has a shape that is substantially the same as that of the first impurity region 222.

The second impurity region 226 doped with N-type impurities is formed in an upper portion of the substrate 200 proximate a sidewall of the second gate electrode 208b. In addition, a portion of the second impurity region 226 is disposed under the second spacer 220b, but no portion of the second impurity region 226 is disposed under the second gate electrode 208b.

Impurities doped into the substrate 200 when forming the second impurity region 226 may be diffused during subsequent processes performed at high temperatures. Thus, the second spacer 220b may be formed to have a relatively large thickness to substantially prevent impurities doped into the substrate 200 when forming the second impurity region 226 from subsequently diffusing to a region of the substrate 200 disposed under the second gate electrode 208b.

After implanting the N-type impurities into the ON cell region, the OFF cell regions, and the NMOS region of the logic circuit region, an ON cell transistor has been formed on the ON cell region, an OFF cell transistor has been formed on the OFF cell region, and an NMOS transistor has been formed on the logic circuit region.

As illustrated in FIG. 6, source regions of the ON cell transistors and OFF cell transistors, each of which is arranged in parallel with one another in the second direction, are connected to one another, thereby forming a common source region S.

The fourth photoresist pattern 221 may be removed using an ashing process and/or a stripping process.

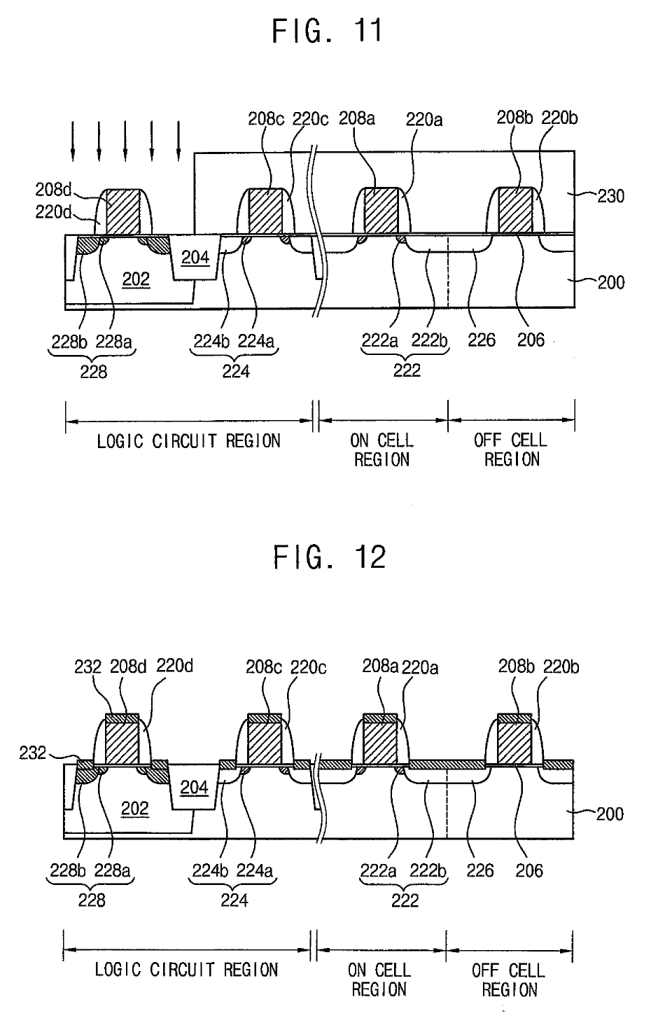

Referring to FIG. 11, a fifth photoresist pattern 230 exposing the PMOS region of the logic circuit region is formed on the substrate 200. Thus, the ON cell region, the OFF cell region, and the NMOS region of the logic circuit region are covered by the fifth photoresist pattern 230.

P-type impurities are implanted with a relatively high concentration into the exposed PMOS region of the logic circuit region of the substrate 200 using the fifth photoresist pattern 230 as an ion implantation mask to form a fourth impurity region 228. That is, the P-type impurities are implanted into an upper portion of the substrate 200 proximate the fourth spacer 220d to form the fourth impurity region 228.

A portion of the fourth impurity region 228 is disposed under a sidewall of the fourth gate electrode 208d, which is disposed in the logic circuit region. In addition, the fourth impurity region 228 may have an LDD structure comprising a third doping region 228a and a fourth doping region 228b. In that case, the third doping region 228a having a third impurity concentration is disposed in an upper portion of the substrate 200 and a portion of the third doping region 228a is disposed under a sidewall of third gate electrode 208d. In addition, the fourth doping region 228b having a fourth impurity concentration is disposed in an upper portion of the substrate 200 and a portion of the fourth doping region 228b is disposed under the fourth spacer 220d.

Thus, the PMOS transistor has been formed in the logic circuit region.

The fifth photoresist pattern 230 may be removed using an ashing process and/or a stripping process.

Referring to FIG. 12, some exposed portions of the gate insulation layer 206 remaining on the substrate 200 are removed through a cleaning process. After performing the cleaning process, only portions of the gate insulation layer 206 disposed under gate electrodes 208a, 208b, 208c, and 208d and spacers 220a, 220b, 220c, and 220d remain on the substrate 200.

A metal layer (not shown) is formed on exposed portions of the substrate 200, the spacers 220a, 220b, 220c, and 220d, and the first through fourth gate electrodes 208a, 208b, 208c, and 208d. The metal layer may be formed from at least one of tungsten, cobalt, titanium, etc.

Additionally, a capping layer (not shown) may be formed on the metal layer. The capping layer may be formed using at least one of titanium, titanium nitride, etc. The capping layer may reduce an interfacial oxidation layer formed on the substrate 200 and the first through fourth electrodes 208a, 208b, 208c, and 208d. Additionally, a silicidation reaction may be generated more stably during a subsequent heat treatment process due to the capping layer.

A heat treatment process is performed on the substrate 200 so that the metal layer reacts with a top surface of the substrate 200 and top surfaces of the first through fourth gate electrodes 208a, 208b, 208c and 208d to form a metal silicide layer pattern 232. That is, the metal silicide layer pattern 232 is formed from the metal layer and the top surface of the substrate 200 and from the metal layer and top surfaces of the first through fourth gate electrodes 208a, 208b, 208c and 208d. In addition, portions of the metal layer disposed on the spacers 220a, 220b, 220c, and 220d do not undergo a reaction and remain unchanged.

When the metal silicide layer pattern 232 is formed, the top surface of the substrate 200 and the top surfaces of the first through fourth gate electrodes 208a, 208b, 208c, and 208d are consumed during the reaction with the metal layer. Therefore, the metal silicide layer pattern 232 is formed such that it is relatively thin to substantially prevent the top surface of the substrate 200 and the top surfaces of the first through fourth gate electrodes 208a, 208b, 208c, and 208d from being consumed excessively.

The heat treatment process for forming the metal silicide layer pattern 232 may comprise a furnace heat treatment process or a rapid thermal process (RTP). The heat treatment process may be performed once or more than once at different temperatures.

The unreacted portions of the metal layer (i.e., the portions of the metal layer that did not undergo a reaction) and the capping layer may be removed using a wet etching process.

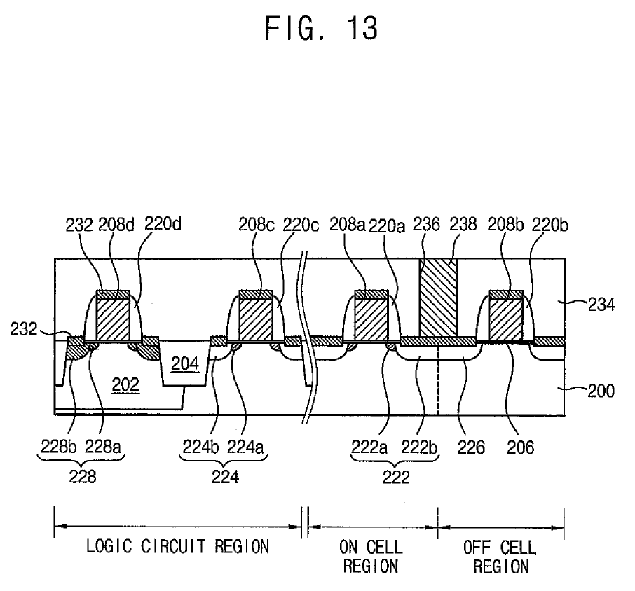

Referring to FIG. 13, an insulating interlayer 234 is formed on the substrate 200 to cover the first through fourth gate electrodes 208a, 208b, 208c, and 208d. The insulating interlayer 234 may be formed using silicon oxide.

Openings 236 are formed through the insulating interlayer 234 exposing at least one impurity region of the first through fourth impurity regions 222, 226, 224, and 228 by etching the insulating interlayer 234. In particular, in the cell region, one opening 236 partially exposes an impurity region that is used as a common drain region of transistors that cross over the isolation layer patterns 204. Additionally, in the cell region, another opening 236 partially exposes common source region S that serves as a common source region for the transistors.

The openings 236 are filled with a conductive material to form a conductive layer, and the conductive layer may be planarized to form plugs 238 that make contact with impurity regions.

A metal line may be formed to connect the plugs 238. The metal line may comprise a bit line, a common source line, etc.

In accordance with embodiments of the invention, the channel region may not be doped with impurities by an implantation process when coding data in a NOR-type mask ROM device, so the working performance and the reliability of the NOR-type mask ROM device may be improved. Additionally, an additional photolithography process for coding data is not performed, thereby simplifying the process for forming the mask ROM device. Therefore, in accordance with an embodiment of the invention, the cost of fabricating a mask ROM device may be reduced.

In accordance with an embodiment of the invention, a mask ROM device having a relatively high degree of integration and a relatively high junction breakdown voltage may be formed. In addition, the mask ROM device may be fabricated through a relatively simple method. Therefore, in accordance with an embodiment of the invention, the reliability of the mask ROM device may be improved and the cost of fabricating the mask ROM device may be reduced.

In accordance with an embodiment of the invention, impurity regions serving as source/drain regions of an ON cell transistor may be disposed partially under a gate electrode of the ON cell transistor, but impurity regions serving as source/drain regions of an OFF cell transistor are not disposed under the gate electrode of the OFF cell transistor. Thus, a channel is not connected to the impurity region of the OFF cell transistor even when a voltage is applied to the gate electrode, so the OFF cell transistor may remain OFF.

In addition, in accordance with an embodiment of the invention, when a mask ROM cell is formed, a relatively high-energy ion implantation process is not performed to code data, so a decrease in a breakdown voltage between a drain region and a substrate may be substantially prevented.

Furthermore, because the relatively high-energy ion implantation process is not performed, an ion implantation mask pattern having a relatively large thickness does not need to be formed.

In accordance with an embodiment of the invention, when fabricating a NOR-type mask ROM device, an ion implantation mask for coding data in the OFF cell transistor may also be used for selectively masking transistors in a logic circuit region. Therefore, an additional photolithography process for forming an ion implantation mask for use in coding data in the OFF cell transistor may not be required, so a method for fabricating a semiconductor device, in accordance with an embodiment of the invention, may be simpler than a method requiring the additional process.

Although embodiments of the invention have been described herein, modifications may be made to the embodiments described herein by one skilled in the art without departing from the scope of the invention as defined by the accompanying claims.

What is claimed is:

1. A mask read-only memory (ROM) cell comprising:
a substrate comprising an ON cell region and an OFF cell region;
a gate insulation layer disposed on the substrate;
a first gate electrode disposed in the ON cell region and on the gate insulation layer;
a second gate electrode disposed in the OFF cell region and on the gate insulation layer;
a first impurity region doped with impurities and disposed in a first upper portion of the substrate proximate a sidewall of the first gate electrode, wherein a portion of the first impurity region is disposed under the sidewall of the first gate electrode; and,
a second impurity region doped with impurities and disposed in a second upper portion of the substrate proximate a sidewall of the second gate electrode, wherein no portion of the second impurity region is disposed under the sidewall of the second gate electrode.

2. The mask ROM cell of claim 1, wherein a first spacer is formed on the sidewall of the first gate electrode and a second spacer is formed on the sidewall of the second gate electrode.

3. The mask ROM cell of claim 2, wherein:
the first impurity region comprises a first doping region having a first impurity concentration and a second doping region having a second impurity concentration;
a portion of the first doping region is disposed under the sidewall of the first gate electrode;
a portion of the second doping region is disposed under the first spacer;
the second doping region makes contact with the first doping region; and,
the second impurity concentration is higher than the first impurity concentration.

4. The mask ROM cell of claim 3, wherein the second impurity region has the second impurity concentration.

5. The mask ROM cell of claim 1, wherein the first and the second gate electrodes comprise polysilicon doped with impurities.

6. The mask ROM cell of claim 1, wherein an edge portion of the first impurity region is connected to an edge portion of the second impurity region.

7. A method for fabricating a mask read-only memory (ROM) cell comprising:
forming a gate insulation layer on a substrate comprising an ON cell region and an OFF cell region;
forming first and second gate electrodes on the gate insulation layer, wherein the first gate electrode is formed in the ON cell region and the second gate electrode is formed in the OFF cell region;
forming a preliminary first impurity region in the ON cell region by implanting first impurities into a first upper portion of the ON cell region proximate the first gate electrode; and,
implanting second impurities into a portion of the substrate proximate a sidewall of the first gate electrode to form a first impurity region and into a portion of the substrate proximate a sidewall of the second gate electrode to form a second impurity region,
wherein:
the first impurity region is disposed in a second upper portion of the ON cell region of the substrate;
the first impurity region comprises the first upper portion of the ON cell region;
the second impurity region is disposed in an upper portion of the OFF cell region of the substrate; and,
no portion of the second impurity region is disposed under the sidewall of the second gate electrode.

8. The method of claim 7, further comprising, after forming the preliminary first impurity region, forming a first spacer on the sidewall of the first gate electrode and forming a second spacer on the sidewall of the second gate electrode.

9. The method of claim 7, wherein forming the preliminary first impurity region in the ON cell region by implanting the first impurities into the first upper portion of the ON cell region proximate the first gate electrode comprises:
forming an ion implantation mask pattern on the substrate to cover the OFF cell region;
implanting impurities into portions of the ON cell region exposed by the ion implantation mask pattern; and,
removing the ion implantation mask pattern.

10. A NOR-type mask read-only memory (ROM) device comprising:
a substrate comprising an ON cell region, an OFF cell region, and a logic circuit region;
a gate insulation layer disposed on the substrate;
a first gate electrode disposed on the gate insulation layer and disposed in the ON cell region;
a second gate electrode disposed on the gate insulation layer and disposed in the OFF cell region;
third and fourth gate electrodes disposed on the gate insulation layer and disposed in the logic circuit region;
a first impurity region having a first conductivity type disposed in a first upper portion of the ON cell region of the substrate proximate a sidewall of the first gate electrode, wherein a portion of the first impurity region is disposed under the sidewall of the first gate electrode;
a first spacer disposed on the sidewall of the first gate electrode;
a second impurity region having the first conductivity type disposed in a first upper portion of the OFF cell region of the substrate proximate a sidewall of the second gate electrode, wherein a portion of the second impurity region is disposed under a second spacer disposed on the sidewall of the second gate electrode;
a third impurity region having the first conductivity type disposed in a first upper portion of the logic circuit region of the substrate proximate a sidewall of the third impurity region;
a third spacer disposed on the sidewall of the third impurity region;
a fourth impurity region having a second conductivity type disposed in a second upper portion of the logic circuit region of the substrate proximate a sidewall of the fourth gate electrode; and,
a fourth spacer disposed on the sidewall of the fourth impurity region.

11. The device of claim 10, further comprising:
an insulating interlayer covering the first through fourth gate electrodes, wherein the insulating interlayer comprises an opening exposing at least one of the first through fourth impurity regions; and,
a plug filling the opening.

12. The device of claim 10, wherein an isolation layer pattern having an island shape is at least partially disposed in a second upper portion of the ON cell region and a second upper portion of the OFF cell region, and the isolation layer extends along a first direction.

13. The device of claim 12, further comprising a conductive line extending in a second direction substantially perpendicular to the first direction, wherein the conductive line comprises the first and second gate electrodes.

14. The device of claim 10, wherein the first and the second gate electrodes comprise polysilicon doped with impurities.

15. The device of claim 14, further comprising a metal silicide layer pattern disposed on the first and second gate electrodes, disposed on a portion of an upper surface of the substrate proximate the first spacer, and disposed on a portion of an upper surface of the substrate proximate the second spacer.

16. The device of claim 10, wherein portions of the first impurity region proximate the sidewall of the first gate electrode are connected to one another to form a common source region extending in the second direction, the portions of the first impurity region serving as source regions.

17. A method for fabricating a NOR-type mask read-only memory (ROM) device, the method comprising:
forming a gate insulation layer on a substrate comprising an ON cell region, an OFF cell region, and a logic circuit region;
forming first through fourth gate electrodes on the gate insulation layer, wherein the first gate electrode is formed in the ON cell region, the second gate electrode is formed in the OFF cell region, and the third and fourth gate electrodes are formed in the logic circuit region;
implanting first impurities having a first conductivity type into a first upper portion of the ON cell region of the substrate proximate the first gate electrode to form a preliminary first impurity region and into a first upper portion of the logic circuit region of the substrate proximate the third gate electrode to form a preliminary third impurity region;
forming a first spacer on a sidewall of the first gate electrode, a second spacer on a sidewall of the second gate electrode, a third spacer on a sidewall of the third gate electrode, and a fourth spacer on a sidewall of the fourth gate electrode;
implanting second impurities having the first conductivity type into a second upper portion of the ON cell region of the substrate proximate the first gate electrode to form a first impurity region, into an upper portion of the OFF cell region of the substrate proximate the second gate electrode to form a second impurity region, and into a second upper portion of the logic circuit region of the substrate proximate the third gate electrode to form a third impurity region; and,
implanting fourth impurities having a second conductivity type into a first upper portion of the substrate proximate the fourth spacer to form a fourth impurity region,
wherein a portion of the first impurity region is disposed under the sidewall of the first gate electrode and a portion of the second impurity region is disposed under the second spacer.

18. The method of claim 17, further comprising:
forming an insulating interlayer on the substrate to cover the first through fourth gate electrodes;
forming an opening exposing at least one of the first to fourth impurity regions by etching the insulating interlayer; and,
filling the opening using a conductive material.

19. The method of claim 17, further comprising forming an isolation layer pattern at least partially in the ON cell region and the OFF cell region of the substrate, wherein the isolation layer pattern has an island shape and extends in a first direction.

20. The method of claim 19, wherein:
forming the first through fourth gate electrodes on the insulation layer comprises forming a conductive line having a linear shape and extending in a second direction substantially perpendicular to the first direction;
the conductive line comprises the first and second gate electrodes; and,
forming the conductive line comprises:
forming a conductive layer on the gate insulation layer; and,
patterning the conductive layer.

21. The method of claim 17, wherein the first through fourth gate electrodes comprise polysilicon doped with impurities.

22. The method of claim 21, further comprising forming a metal silicide layer pattern from a metal layer and the first through fourth gate electrodes and from the metal layer and upper surfaces of the substrate proximate the first through fourth spacers.

23. The method of claim 17, further comprising:
before implanting the first impurities, forming an ion implantation mask pattern on the substrate; and,
after implanting the first impurities, removing the ion implantation mask, wherein:
the ion implantation mask pattern covers the OFF cell region and a first region of the logic circuit region;
the ion implantation mask pattern exposes the first upper portion of the ON cell region and a second region of the logic circuit region;
the fourth gate electrode is formed in the first region of the logic circuit region; and,
the third gate electrode is formed in the second region of the logic circuit region.

24. The method of claim 17, further comprising, prior to forming the fourth gate electrode, forming a channel region in a third upper portion of the logic circuit region of the substrate by implanting impurities having the first conductivity type into the third upper portion of the logic circuit region,
wherein the fourth gate electrode is subsequently formed on the third upper portion of the logic circuit region.
